(19) United States
(12) Patent Application Publication
(10) Pub. No.: US 2011/0033620 A1
(43) Pub. Date: Feb. 10, 2011

(54) COMPOUND LIFT PIN TIP WITH TEMPERATURE COMPENSATED ATTACHMENT FEATURE

(75) Inventors: Alexander S. Polyak, San Jose, CA (US); Tom K. Cho, Los Altos, CA (US); Oscar Gomez, San Francisco, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/848,782

(22) Filed: Aug. 2, 2010

Related U.S. Application Data
(60) Provisional application No. 61/232,098, filed on Aug. 7, 2009.

(51) Int. Cl. C23C 16/458; C23C 16/00

(52) U.S. Cl. 427/248.1; 118/500

(57) ABSTRACT

A method and apparatus for a lift pin is described. In one embodiment, a lift pin head is described. The lift pin head includes a base member having a body made of a first material having a first coefficient of thermal expansion, and a tip disposed on the base member, the base member having a body made of a second material that is flexible at room temperature and having a second coefficient of thermal expansion, the first coefficient of thermal expansion being less than the second coefficient of thermal expansion.

### CROSS-REFERENCE TO RELATED APPLICATIONS

This application claims benefit of U.S. provisional patent application Ser. No. 61/232,098, filed Aug. 7, 2009, which is incorporated by reference herein.

### BACKGROUND OF THE INVENTION

1. Field of the Invention

Embodiments of the invention generally relate to a support device for supporting a substrate. More particularly, embodiments of the invention relate to a lift pin for use in a vacuum chamber utilized to deposit materials on flat media, such as rectangular, flexible sheets of glass, plastic or other material in the manufacture of flat panel displays, photovoltaic devices or solar cells, among other applications.

2. Description of the Related Art

Electronic devices, such as thin film transistors (TFT's), photovoltaic (PV) devices or solar cells and other electronic devices have been fabricated on thin media for many years. The thin media is generally a discrete tile, a wafer, a sheet or other substrate having a major side with a surface area less than one square meter. However, there is an ongoing effort directed to fabricating the electronic devices on substrates having a surface area much greater than one square meter, such as two square meters, or larger, to produce an end product of a larger size and/or decrease fabrication costs per device (e.g., pixel, TFT, photovoltaic or solar cell, etc.).

The ever-increasing size of these substrates presents numerous handling challenges. Numerous lift pins are typically utilized to facilitate transfer of the substrates into or out of a processing chamber. The thin media is highly flexible at room temperature and becomes even more flexible at temperatures inside the processing chamber. In order to provide rigidity, each lift pin is made of a material that is resistant to these high processing temperatures. However, the portion of the lift pin that contacts the substrate may scratch or otherwise damage the substrate. Scratching of the substrate or damage to the substrate generates particles, causes system downtime and/or costly loss of product, which decreases throughput and profitability.

What is needed is an improved lift pin that is adapted to withstand processing temperatures and minimizes scratching or damage to the substrate by reducing friction between the substrate and the lift pin.

### SUMMARY OF THE INVENTION

Embodiments described herein relate to a lift pin for supporting and/or facilitating transfer of a flexible substrate. In one embodiment, a support pedestal for a vacuum chamber is provided. The support pedestal includes a support body having a having a plurality of openings formed between two major sides thereof, and a lift pin disposed in each of the openings, the lift pin comprising an elongated shaft coupled to a head, the head comprising a base member having a body made of a first material, the first material having a first coefficient of thermal expansion, and a tip disposed on the base member, the base member having a body made of a second material that is flexible at room temperature and having a second coefficient of thermal expansion, the first coefficient of thermal expansion being less than the second coefficient of thermal expansion.

In another embodiment, a lift pin adapted for use in a vacuum chamber is provided. The lift pin includes an elongated shaft coupled to a head, the head comprising a base member having a body made of a first material, the first material having a first coefficient of thermal expansion, and a tip disposed on the base member, the base member having a body made of a second material that is flexible at room temperature and having a second coefficient of thermal expansion, the first coefficient of thermal expansion being less than the second coefficient of thermal expansion.

In another embodiment, a method for processing a substrate is provided. The method includes depositing one or more layers onto a substrate disposed on a substrate support in a vacuum deposition chamber, and lifting the substrate from the substrate support with a lift pin having a tip made of a conformal polymer material disposed on a metallic base, wherein the tip has a coefficient of expansion that is greater than a coefficient of expansion of the metallic base.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross-sectional view of one embodiment of a processing system.

FIG. 1B is a schematic cross-sectional view of the processing system of FIG. 1A showing the substrate support in a transfer position.

FIG. 1C is an enlarged view of a portion of the substrate support of FIG. 1A.

FIG. 2A is a partial cross-sectional view a lift pin showing one embodiment of a head.

FIG. 2B is a top view of the base member of the head shown in FIG. 2A.

FIG. 2C is a bottom view of the tip of the head shown in FIG. 2A.

FIG. 3A shows one embodiment of a procedure for installing a tip.

FIG. 3B is a cross-sectional view of the head of FIG. 3A showing an atmospheric coupling interface.

FIG. 3C is a cross-sectional view of the head of FIG. 3B showing an elevated temperature coupling interface.

FIG. 4A is a top view of another embodiment of a lift pin shaft.

FIG. 4B is a side view of the lift pin shaft of FIG. 4A having a tip and a base member.

FIG. 4C is a side view of the head and lift pin of FIG. 4B.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally provide a method and apparatus for supporting, transferring and/or handling flexible media, which is particularly suitable for rectangular media having at least one major side with a surface area greater than one square meter, such as greater than about two square meters, or larger. In one embodiment, a lift pin to support or facilitate transfer the flexible, rectangular media is described. The lift pin includes a contact tip having a base and a tip made of dissimilar materials. In one embodiment, the tip is made of a material that may expand and contract based on temperature variations. The lift pin may be used in a vacuum chamber adapted to deposit materials on the media to form electronic devices such as thin film transistors, organic light emitting diodes, photovoltaic devices or solar cells. The flexible media as described herein may be thin sheet of metal, plastic, organic material, silicon, glass, quartz, or polymeric materials, among other suitable materials.

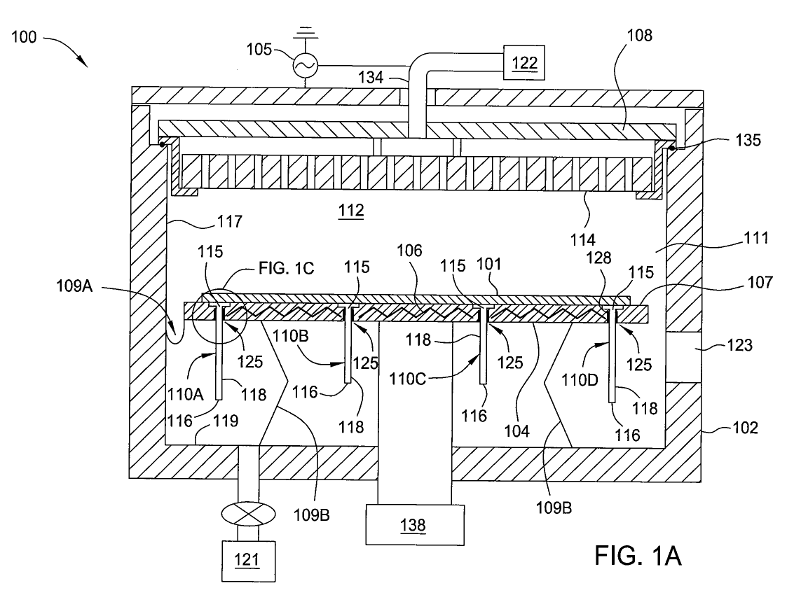

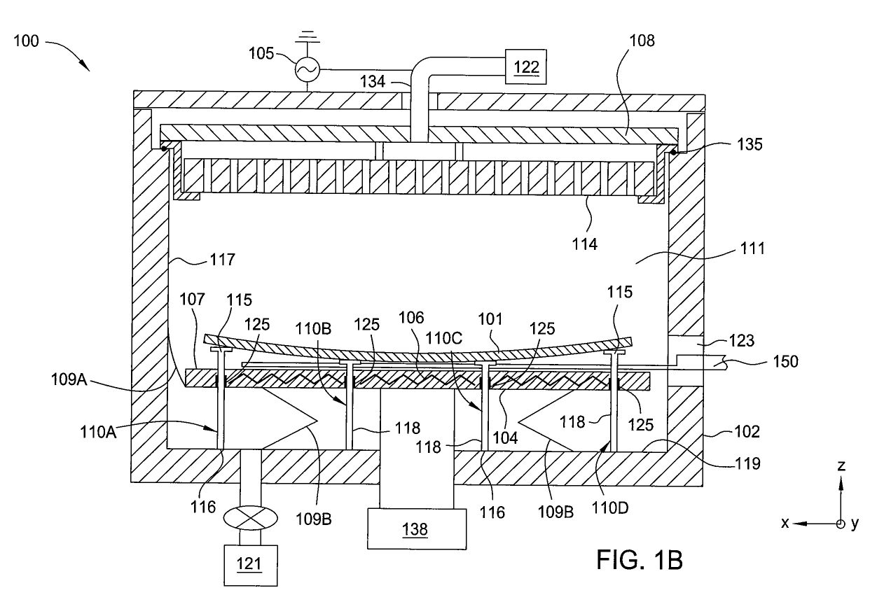

FIG. 1A is a schematic cross-sectional view of one embodiment of a processing system 100. In one embodiment, the processing system 100 is configured to process flexible media, such as a large area substrate 101, using plasma to form structures and devices on the large area substrate 101. The structures formed by the processing system 100 may be adapted for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters. The structures may include one or more junctions used to form part of a thin film photovoltaic device or solar cell. In another embodiment, the structures may be a part of a thin film transistor (TFT) used to form a LCD or TFT type device. It is also contemplated that the processing system 100 may be adapted to process substrates of other sizes and types, and may be used to fabricate other structures.

As shown in FIG. 1A, the processing system 100 generally comprises a chamber body 102 including a sidewall 117, a bottom 119 and a lid 108 defining a processing volume 111. A support pedestal or substrate support 104 is disposed in the processing volume 111 opposing a showerhead assembly 114. The substrate support 104 is adapted to support the substrate 101 on an upper or support surface 107 during processing. The substrate support 104 is also coupled to an actuator 138 configured to move the substrate support 104 at least vertically to facilitate transfer of the substrate 101 and/or adjust a distance between the substrate 101 and a showerhead assembly 114. One or more lift pins 110A-110D extend through the substrate support 104 through respective bushings 125. Each of the lift pins 110A-110D are movably disposed within a dedicated bushing 125 that is disposed within openings 128 formed in the substrate support 104. Each of the lift pins 110A-110D include an upper or first end 115 and a lower or second end 116 at opposing ends of an elongated shaft 118. The first end 115 includes at least a contact portion having an upper surface that is adapted to contact the substrate 101.

In the embodiment shown in FIG. 1A, the substrate support 104 is shown in a processing position near the showerhead assembly 114. In the processing position, the lift pins 110A-110D are adapted to be flush with or slightly below the support surface 107 of the substrate support 104 to allow the substrate 101 to lie flat on the substrate support 104. A processing gas source 122 is coupled by a conduit 134 to deliver process gases through the showerhead assembly 114 and into the processing volume 111. The processing system 100 also includes an exhaust system 121 configured to apply and/or maintain negative pressure to the processing volume 111. A radio frequency (RF) power source 105 is coupled to the showerhead assembly 114 to facilitate formation of a plasma in a processing region 112. The processing region 112 is generally defined between the showerhead assembly 114 and the support surface 107 of the substrate support 104.

The showerhead assembly 114, the lid 108, and the conduit 134 are generally formed from electrically conductive materials and are in electrical communication with one another. The chamber body 102 is also formed from an electrically conductive material. The chamber body 102 is generally electrically insulated from the showerhead assembly 114. In one embodiment, the showerhead assembly 114 is mounted on the chamber body 102 by an insulator 135. In one embodiment, the substrate support 104 is also electrically conductive, and the substrate support 104 is adapted to function as a shunt electrode to facilitate a ground return path for RF energy. In one embodiment, the showerhead assembly 114, the lid 108, the conduit 134 and the substrate support are made of an aluminum material.

A plurality of electrical return devices 109A, 109B may be coupled between the substrate support 104 and the sidewall 117 and/or the bottom 119 of the chamber body 102. Each of the return devices 109A, 109B are flexible and/or spring-like devices that bend, flex, or are otherwise selectively biased to contact the substrate support 104, the sidewall 117 and/or the bottom 119. In one embodiment, at least a portion of the plurality of return devices 109A, 109B are thin, flexible straps that are coupled between the substrate support 104, the sidewall 117 and/or the bottom 119. In one example, the substrate support 104 may be coupled to an earthen ground through at least a portion of the plurality of return devices 109A, 109B. Alternatively or additionally, the return path may be directed by at least a portion of the plurality of return devices 109A, 109B back to the RF power source 105. In this embodiment, returning RF current will pass along the interior surface of the bottom 119 and/or sidewall 117 to return to the RF power source 105.

Using a process gas from the processing gas source 122, the processing system 100 may be configured to deposit a variety of materials on the large area substrate 101, including but not limited to dielectric materials (e.g., SiO₂, SiOₓN_{y}, derivatives thereof or combinations thereof), semiconductive materials (e.g., Si and dopants thereof), barrier materials (e.g., SiN_{X}, SiOₓN_{y} or derivatives thereof). Specific examples of dielectric materials and semiconductive materials that are formed or deposited by the processing system 100 onto the large area substrate may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the processing system 100 may be accomplished by using silane as the precursor gas in a hydrogen carrier gas. The showerhead assembly 114 is generally disposed opposing the substrate support 104 in a substantially parallel manner to facilitate plasma generation therebetween.

A temperature control device 106 is also disposed within the substrate support 104 to control the temperature of the substrate 101 before, during, or after processing. In one aspect, the temperature control device 106 comprises a heating element to preheat the substrate 101 prior to processing. In this embodiment, the temperature control device 106 may heat the substrate support 104 to a temperature between about 100° C. and about 300° C., such as a temperature between 100° C. to about 200° C. During processing, temperatures in the processing region 112 may be between about 100° C. to about 400° C., such as a temperature between about 200° C. to about 250° C. In some processes, temperatures in the processing region may reach or exceed 450° C. and the temperature control device 106 may comprise one or more coolant channels to cool the substrate support 104 and/or the substrate 101 during processing. In another aspect, the temperature control device 106 may function to cool the substrate 101 after processing. Thus, the temperature control device 106 may be coolant channels, a resistive heating element, or a combination thereof.

FIG. 1B is a schematic cross-sectional view of the processing system 100 of FIG. 1A illustrating the substrate support 104 in a transfer position. In the transfer position, the substrate 101 is positioned in a spaced-apart relationship relative to the support surface 107 of the substrate support 104. In the spaced-apart position, the substrate 101 may be removed by a robotic device. While not shown in the cross-sectional views of FIGS. 1A and 1B, the substrate support 104 includes at least eight lift pins, such as lift pins 110A-110D, although any number of lift pins may be utilized. The number of lift pins may be determined by the size of the substrate 101 and/or the deflection of the substrate 101.

In one embodiment, the substrate 101 is lifted away from the support surface 107 in an edge first/center last manner. The edge first/center last transfer method causes the substrate 101 to be lifted and supported by the lift pins 110A-11D in a bowed orientation. During processing, electrostatic charges build up between the substrate 101 and the support surface 107. After processing, a portion of this electrostatic charge remains and serves to adhere the substrate 101 to the support surface 107. The edge first/center last lifting method eases lifting of the substrate 101 by minimizing the force needed to break the residual electrostatic attraction and/or redistribute residual electrostatic forces that results in less lifting force being used. Likewise, the transfer method for a to-be-processed substrate is performed in a center first/edge last manner. The center first/edge last lowering method allows better contact between the substrate 101 and the support surface 107. For example, any air that is present between the support surface 107 and the substrate 101 is allowed to escape as the substrate 101 is lowered toward the substrate support 104.

In order to promote transfer of the substrate 101 in a bowed orientation, the lift pins 110A-110D are divided into groups, such as outer lift pins for perimeter support and inner lift pins for center support. The groups of lift pins are actuated at different times and/or adapted to extend different lengths (or heights) above the support surface 107 to position the substrate 101 in the bowed orientation. In one embodiment, the outer lift pins 110A, 110D are longer than the inner lift pins 110B, 110C. In this embodiment, the second end 116 of the lift pins 110A-110D are adapted to contact the bottom 119 of the chamber body 102 and support the substrate 101 when the substrate support 104 is lowered by the actuator 138. The different lengths of the lift pins 110A, 110D and 110B, 110C allow the substrate 101 to be raised (or lowered) in a bowed orientation. In the transfer position, the support surface 107 of the substrate support 104 is substantially aligned with a transfer port 123 formed in the sidewall 117 which allows a blade 150 of a robot to move in the X direction between or around the lift pins 110A-110D, and between the substrate 101 and the support surface 107. To remove the substrate from this position, the blade 150 moves vertically upwards (Z direction) to lift the substrate 101 from the lift pins 110A-110D. The blade-supported substrate may then be removed from the chamber body 102 by retracting the blade 150 in the opposite X direction. Likewise, to place a to-be-processed substrate 101 on the lift pins 110A-110D, the blade 150 moves vertically downwards (Z direction) to position the substrate on the extended lift pins 110A-110D.

FIG. 1C is an enlarged view of a portion of the lift pin 110A, the bushing 125 and a portion of the substrate support 104 of FIG. 1A. The lift pin 110A includes a head 160 having a cap or tip 165 disposed on a base member 170. In one embodiment, the tip 165 is configured as an insert that is easily removed and replaceable on the base member 170. The tip 165 and base member 170 are made of different materials. In one embodiment, the base member 170 is made from a material having a first coefficient of thermal expansion and the tip 165 is made from a second material having a second coefficient of thermal expansion. In this embodiment, the second coefficient of thermal expansion is greater than the first coefficient of thermal expansion.

In one embodiment, the base member 170 is made of a material that is rigid at room temperature and/or at processing temperatures while the tip 165 is made of a material that is flexible at room temperature and/or at processing temperatures. Examples of the materials for the base member 170 include materials that can withstand high temperatures and are not reactive with process chemistry, such as a metal or metal alloy, or a ceramic material. Examples of metals or metallic alloys include aluminum, titanium, stainless steel, or other metal that does not react with process chemistry. Examples of materials for the tip 165 include materials that retain physical properties at high temperatures (i.e. temperatures of about 200° C. to about 500° C.) and are not reactive with process chemistry. Examples of materials for the tip 165 include plastic materials, for example polyetheretherketone (PEEK), polytetrafluoroethylene (PTFE), such as a TEFLON® material, polyamide-imide materials, such as a TORLON® material, as well as polyimide materials, such as a VESPEL® material.

In this embodiment, the base member 170 is formed on the elongated shaft 118 such that the elongated shaft 118 and base member may be manufactured as an integrated element. The shaft 118 may be fabricated from a metal or metal alloy, or a ceramic material. Examples of metals or metallic alloys include aluminum, titanium, stainless steel, or other metal that does not react with process chemistry. The shaft 118 is configured to be supported by and movable within the bushing 125 in the substrate support 104. The bushing 125 provides support and relative movement of the shaft 118 with minimal friction. In one embodiment, the bushing 125 includes a body 175 that contains a plurality of bearing elements 180 that contact the shaft 118. However, the bushing 125 may be a simple sleeve or hole having a bore that allows relative movement of the shaft 118 therein. The body 175 and bearing elements 180 may be made of process compatible materials, such as a ceramic or a crystal material, such as sapphire, ruby, quartz and combinations thereof. The body 175 of the bushing 125 may be secured in the substrate support 104 by a support body 190 that may be fastened to the substrate support 104.

In operation, when the substrate support 104 is in the processing position, as shown in FIG. 1A, an upper surface of the tip 165 is disposed flush with or slightly lower than a plane of the support surface 107 of the substrate support 104. In one embodiment, at least a portion of the head 160 is configured to expand during processing. In one embodiment, the opening 128 includes a stepped bore or channel having multiple dimensions. The opening 128 may include a first dimension (or diameter) that is sized to receive the head 160 and a second dimension (or diameter) that is less than the first dimension that is sized to receive the bushing 125. In one embodiment, a recessed gap 195 is provided in the substrate support 104 that facilitates any thermal expansion of the head 160 when the head 160 is exposed to elevated processing temperatures. The gap 195 is bounded by sidewalls and includes an inside dimension that is larger than the outer dimension of the head 160 but smaller than a dimension of the remainder of the opening 128. The gap 195 also includes a depth dimension that is configured to receive the thickness dimension of the head 160 and allows the upper surface of the tip 165 to be flush with or slightly recessed from a plane of the support surface 107. In this manner, the head 160 fills any voids in the support surface 107 caused by placement of the bushing 125 in the substrate support 104. The bushing 125 and the head 160 are at least partially thermally conductive in order to transfer thermal energy to and from the substrate 101 and substrate support 104. The bushing 125, in combination with the head 160, enhances heating or cooling of the substrate 101, which minimizes or eliminates “cold spots” on the substrate 101. The uniform temperature distribution enabled by the bushing 125 and head 160 facilitates uniform deposition on the substrate 101.

When the substrate support 104 is moving to a transfer position (lowered in the −Z direction), the head 160 maintains the lift pin 110A in a substantially vertical orientation (Z direction) until the second end 116 of the lift pin 110A contacts the bottom 119 (FIGS. 1A and 1B) of the chamber body 102. After contacting the bottom 119 of the chamber body 102, the lift pin 110A becomes stationary relative to the substrate support 104, which continues movement in the −Z direction. As the substrate support 104 moves relative to the lift pin 110A, the bearing elements 180 contact the shaft 118 and allow relative movement of the shaft 118 in the bushing 125. The movement of the substrate support 104 causes the head 160 to extend away from the support surface 107 in the +Z direction, lifting and spacing the substrate 101 from the support surface 107 of the substrate support 104.

The suspension of the lift pin 110A by the head 160 allows the lift pin 110A to move with the substrate support 104 during vertical movement of the substrate support 104. The suspension of the lift pin 110A also allows the second end 116 of the lift pin 110A to be free-floating such that any lateral misalignment between the bottom 119 (FIGS. 1A and 1B) of the chamber body 102 and the second end 116 of the lift pin 110A will not cause binding or breakage of the lift pin 110A.

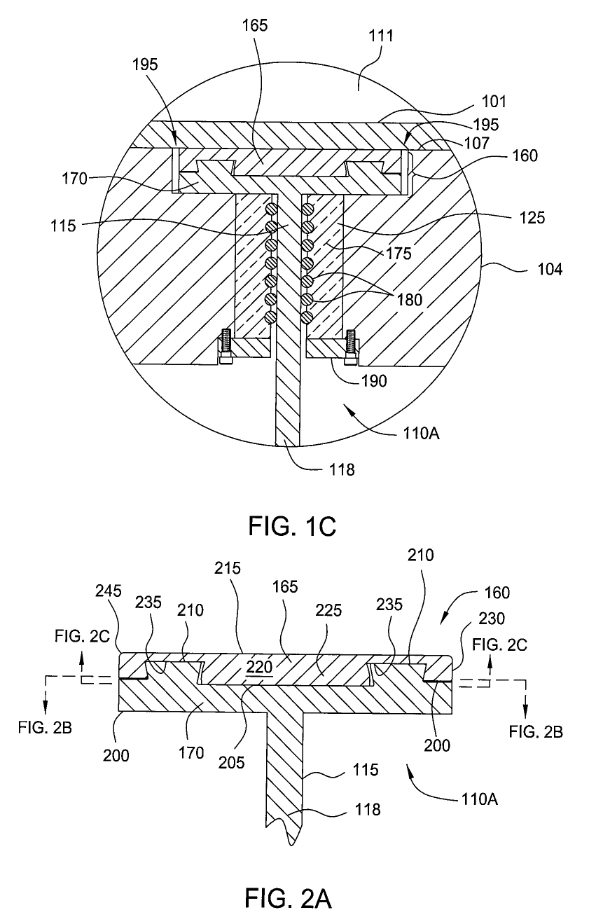

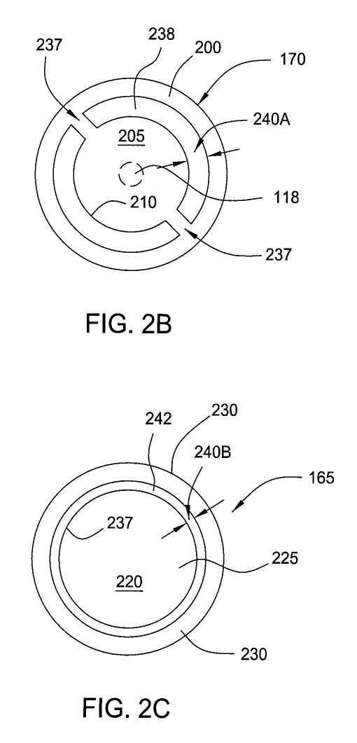

FIG. 2A is a partial cross-sectional view a lift pin 110A showing one embodiment of a head 160. In this embodiment, the base member 170 includes a multi-plane upper surface which includes a perimeter 200 having a first thickness and a recessed center surface 205 having a second thickness that is less than the first thickness. The perimeter 200 and the center surface 205 are separated by a ridge 210 that functions as a mating interface between the base member 170 and the tip 165. The tip 165 includes a planar upper surface or contact face 215 and a lower surface having a varied thickness to substantially conform to the perimeter 200 and center surface 205 of the base member 170. For example, the tip 165 includes a body 220 having a center portion 225 and a perimeter portion 230 and the center portion 225 has a thicker cross-section than the cross-section of the perimeter portion 230. The center portion 225 and the perimeter portion 230 of the tip 165 are separated by a channel 235 that mates with the ridge 210 of the base member 170. The tip 165 also includes a peripheral edge 245 that may be a chamfered surface or include a radius. In one embodiment, the peripheral edge 245 includes a radius of about 0.02 inches.

FIG. 2B is a top view of the base member 170 of the head 160 shown in FIG. 2A. In this embodiment, the base member 170 is round or circular. The ridge 210 is annular and, in one embodiment, includes one or more gaps 237 that are configured to facilitate thermal expansion of the base member 170 and/or the tip 165. In one embodiment, the face 215 that has a width dimension 240A that is greater than a dimension of the channel 235 of the tip 165.

FIG. 2C is a bottom view of the tip 165 of the head 160 shown in FIG. 2A. In this embodiment, the tip 165 is round or circular and includes an outside dimension that is substantially equal to the outside dimension of the base member 170 at ambient or room temperature. Likewise, the channel 235 is annular or circular and includes an opening 242 having a width dimension 240B that is less than a width dimension 240A of a face 238 of the ridge 210.

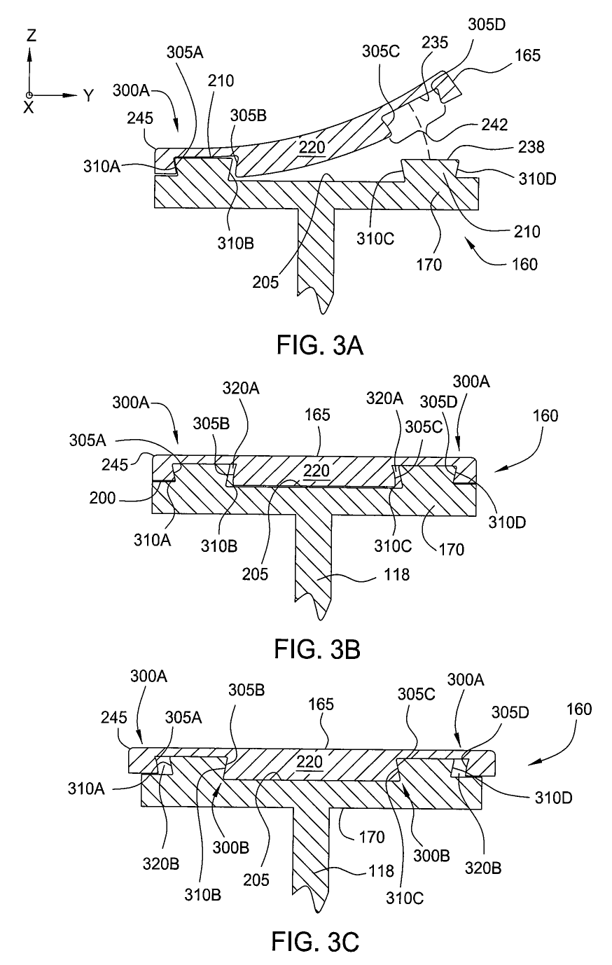

FIGS. 3A-3C are cross-sectional views of a head 160. FIG. 3A shows an installation position of the tip 165 using an atmospheric coupling interface 300A between the tip 165 and the base member 170. As described above, the tip 165 is flexible and may be bent as shown in FIG. 3A. Each of the channel 235 of the tip 165 and the ridge 210 of the base member include sloping sidewalls 305A-305D and 310A-310D, respectively. To install the tip 165 on the base member 170, the sloping sidewall 305A of the channel 235 is brought onto contact with the sloping sidewall 310A of the ridge 210 while the tip 165 is bent. Bending of the tip 165 makes the opening 242 larger and allows the ridge 210 to be received by the channel 235. Likewise, the tip 165 may be manipulated, such as by bending or pressing the tip 165 against the ridge 210 on the opposite side of the tip 165, to allow the sloping sidewalls 305C and 305D to clear the face 238 of the ridge 210. The tip 165 may also be manipulated to allow one or both of the sloping sidewalls 305C and 305D to clear the face 238 of the ridge 210 by moving the tip 165 laterally (Y direction). In one embodiment, one or all of the sidewalls 305A-305D are press-fit or snap-fit to couple with or contact one or more of the sidewalls 310A-310D of the ridge 210. While not shown, it is understood that the base member 170 may be rotated while the tip 165 is bent, pressed, laterally moved or otherwise manipulated to allow the channel 235 to envelop the ridge 210. When the sidewalls 305C and 305D clear the face 238, the body 220 of the tip 165 contacts the center surface 205 of the base member 170, as shown in FIG. 3B, and the tip 165 is installed. The tip 165 may be removed from the base member 170 by bending or peeling the tip 165 away from the base member 170 in manner that is opposite to the installation procedure described above.

FIG. 3B is a cross-sectional view of the head 160 of FIG. 3A showing the atmospheric coupling interface 300A at ambient or room temperature (e.g., about 20° C. to about 25° C.). At ambient temperature, the tip 165 is coupled to the base member 170 by one or a combination of contact between the sidewalls 305A and 310D, and the sidewalls 305D and 310D. Additionally, a first gap 320A is present between sidewalls 305B and 310B as well as between the sidewalls 305C and 310C. The atmospheric coupling interface 300A allows the tip 165 to be secured to the base member 170 at ambient temperatures while the first gap 320A provides space for thermal expansion of the tip 165. In one aspect, the first gap 320A functions as a thermal expansion compensation element that provides for thermal expansion of the tip 165 when the head 160 is exposed to temperatures above ambient temperature, such as elevated temperatures utilized during processing, for example, temperatures between about 200° C. to about 250° C.

FIG. 3C is a cross-sectional view of the head 160 of FIG. 3B showing an elevated temperature coupling interface 300B of the head 160. During processing, the head 160 may be subject to temperatures between about 200° C. to about 250° C. In response to the elevated temperatures, at least the tip 165 expands radially relative to the base member 170. The expansion of the tip 165 causes the first gap 320A to minimize and forms a second gap 320B on the opposing side of the ridge 210. The minimization of the first gap 320A promotes contact between the sidewalls 305B and 310B, and the sidewalls 305C and 310C which facilitates securing of the tip 165 on the base member 170 during processing.

In the embodiment shown in FIGS. 3A-3C, the base member 170 is made from a material having a first coefficient of thermal expansion and the tip 165 is made from a second material having a second coefficient of thermal expansion, and the second coefficient of thermal expansion is greater than the first coefficient of thermal expansion. For example, the base member 170 may be made of an aluminum alloy, such as 6061-T6 aluminum having a coefficient of thermal expansion (CTE) of about 1.23×10⁻⁵/° F. at 380° F. The tip 165 may be made of a material having a CTE that is about six to seven orders of magnitude greater than the CTE of the base member 170. In this example, the tip may be made of a PTFE compound having a CTE of about 7.5×10⁻⁵/° F. at 380° F.

The difference in the CTE's of each of the base member 170 and tip 165 cause relative expansion and contraction, which allows coupling of the tip 165 to the base member 170 at ambient and elevated temperatures. In one example, the atmospheric coupling interface 300A has a diameter defined between the sidewalls 305B, 305C and 310B, 310D that is about 0.232 inches at room temperature. At elevated temperatures, the diameter defined between the sidewalls 305B, 305C of the tip 165 increases to about 0.238 inches, while the diameter defined between the sidewalls 310B, 310C of the base member 170 increases to about 0.233 inches. Thus, the diameter defined between the sidewalls 305B, 305C of the tip 165 increases by a factor of about 6 relative to the diameter defined between the sidewalls 310B, 310C of the base member 170.

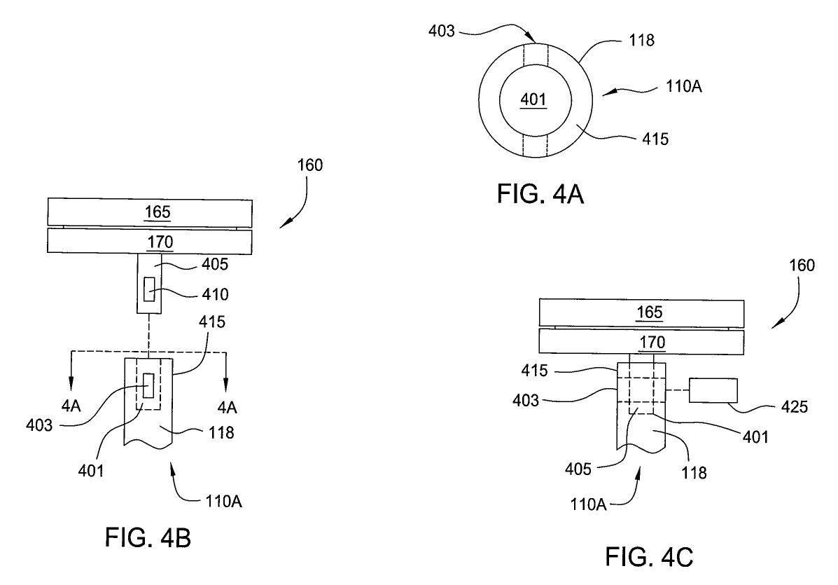

FIGS. 4A-4C are various views of an alternative embodiment of a lift pin 110A utilizing embodiments the head 160 as described herein. FIG. 4A is a top view of a lift pin 110A having a shaft 118 that is substantially similar to shaft 118 described in FIGS. 1A-1C with the exception of a modified first end 415. The first end 415 includes a longitudinal bore 401 and a transverse bore 403 adapted to receive a head 160.

FIG. 4B is a side view of a head 160 having a tip 165 and a base member 170 as described in FIGS. 2A-3C. The base member 170 in this embodiment includes a shaft 405 extending therefrom that is adapted to be received by the longitudinal bore 401 on the first end 415 of the shaft 118. The shaft 405 of the base member 170 includes an opening 410 that substantially aligns with the transverse bore 403 on the first end 415 of the shaft 118.

FIG. 4C is a side view of the head 160 and lift pin 110A of FIG. 4B that has been rotated 90° showing the shaft 405 of the base member 170 disposed in the longitudinal bore 401 of the shaft 118. A fastener 425 is inserted into the transverse bore 403 and the opening 410 to fasten the shaft 118 to the head 160. The fastener 425 may be a key, a wedge or a roll pin, among other types of fasteners.

Testing of the tip 165 was performed utilizing different materials for the tip 165 in order to determine surface damage of the various materials on glass coupons. The materials for the tip 165 included plastics, such as PEEK, TORLON® and VESPEL® materials, as well as various metals. The tip 165 was dropped in a free-fall at a distance of 1.0 meter onto the glass coupons. Weights were attached to the tips 165 comprising metallic materials until the glass coupon broke twice with the same weight. The free-fall test was performed on tips 165 comprising plastic materials utilizing the same weighting determined by the tips 165 comprising metallic materials. After the drop test, glass coupons were rubbed manually with the peripheral edge 245 of the tip 165 in an attempt to produce scratches on the glass coupons. None of the tips 165 comprising plastics broke the glass coupons or scratched the glass coupons as compared to the metallic materials utilizing similar weighting and rubbing pressure.

While the foregoing is directed to embodiments of the invention, other and further embodiments of the invention may be devised without departing from the basic scope thereof.

What is claimed is:

1. A support pedestal for a vacuum chamber, comprising;
a support body having a having a plurality of openings formed between two major sides thereof; and
a lift pin disposed in each of the openings, the lift pin comprising:
an elongated shaft coupled to a head, the head comprising:
a base member having a body made of a first material, the first material having a first coefficient of thermal expansion; and
a tip disposed on the base member, the base member having a body made of a second material that is flexible at room temperature and having a second coefficient of thermal expansion, the first coefficient of thermal expansion being less than the second coefficient of thermal expansion.

2. The support pedestal of claim 1, wherein the elongated shaft is made of a third material having a third coefficient of thermal expansion that is different than the coefficient of thermal expansion of the first material and the second material.

3. The support pedestal of claim 1, wherein the support body is made of a material having a coefficient of thermal expansion that is substantially equal to the first coefficient of thermal expansion.

4. The support pedestal of claim 1, wherein the elongated shaft is fabricated from a ceramic material.

5. The support pedestal of claim 4, wherein the base member is fabricated from an aluminum material.

6. The support pedestal of claim 4, wherein the tip is fabricated from a plastic material.

7. The support pedestal of claim 1, wherein the lift pin further comprises:
a tubular portion at one end of the elongated shaft adjacent the head.

8. The support pedestal of claim 7, wherein the base member includes a shaft that is at least partially disposed in a bore of the tubular portion.

9. A lift pin adapted for use in a vacuum chamber, the lift pin comprising:
an elongated shaft coupled to a head, the head comprising:
a base member having a body made of a first material, the first material having a first coefficient of thermal expansion; and
a tip disposed on the base member, the base member having a body made of a second material that is flexible at room temperature and having a second coefficient of thermal expansion, the first coefficient of thermal expansion being less than the second coefficient of thermal expansion.

10. The lift pin of claim 9, wherein the elongated shaft is made of a third material having a third coefficient of thermal expansion that is different than the coefficient of thermal expansion of the first material and the second material.

11. The lift pin of claim 10, wherein the elongated shaft is fabricated from a ceramic material.

12. The lift pin of claim 9, wherein the base member is fabricated from an aluminum material.

13. The lift pin of claim 9, wherein the tip is fabricated from a plastic material.

14. The lift pin of claim 9, further comprising:
a tubular portion at one end of the elongated shaft adjacent the head.

15. The lift pin of claim 14, wherein the base member includes a shaft that is at least partially disposed in a bore of the tubular portion.

16. The lift pin of claim 15, wherein the shaft of the base member and the tubular portion include a keyway formed radially therethrough, the lift pin further comprising:
a key disposed in the keyway coupling the base member to the elongated shaft.

17. The lift pin of claim 11, wherein the second coefficient of thermal expansion is at least six times greater than the first coefficient of thermal expansion.

18. A method for processing a substrate, comprising:
depositing one or more layers onto a substrate disposed on a substrate support in a vacuum deposition chamber; and
lifting the substrate from the substrate support with a lift pin having a tip made of a conformal polymer material disposed on a metallic base, wherein the tip has a coefficient of expansion that is greater than a coefficient of expansion of the metallic base.

19. The method of claim 18, wherein the coefficient of expansion of the tip is at least about six times greater than the coefficient of expansion of the base.

20. The method of claim 18, wherein the lift pin comprises a base member having a ridge extending from a first side thereof and a tip having an annular channel formed therein, wherein:
a first gap is formed between an inside dimension of the annular channel and an inside dimension of the ridge at room temperature; and
a second gap is formed between the outside dimension of the annular channel and the outside dimension of the ridge during deposition of the one or more layers onto the substrate.
